(19) United States
(12) Patent Application Publication
(10) Pub. No.: US 2026/0021440 A1
(43) Pub. Date: Jan. 22, 2026

(54) SYSTEM AND METHOD FOR PROCESS CHEMISTRY ABATEMENT AND RECYCLING

(71) Applicant: Tokyo Electron Limited, Tokyo (JP)

(72) Inventor: Lauren M. Otto, Richfield, MN (US)

(21) Appl. No.: 19/270,272

(22) Filed: Jul. 15, 2025

Related U.S. Application Data
(60) Provisional application No. 63/674,193, filed on Jul. 22, 2024.
(60) Provisional application No. 63/676,332, filed on Jul. 27, 2024.

(51) Int. Cl. B01D 53/04; B01D 39/12; B01D 53/68; B01D 53/81; H01L 21/67

(52) U.S. Cl. CPC B01D 53/0446; B01D 39/12; B01D 53/0454; B01D 53/685; B01D 53/81; B01D 2251/304; B01D 2251/404; B01D 2251/602; B01D 2251/608; B01D 2253/204; B01D 2257/2027; B01D 2257/204; B01D 2257/30; B01D 2258/0216; B01D 2259/40003; B01D 2259/40088; H01L 21/67017

(57) ABSTRACT

A processing system is provided for capturing and recycling process gases from semiconductor manufacturing operations. The system includes a process chamber configured to process a substrate and an exhaust system coupled to the process chamber and configured to remove process effluent from the process chamber. An abatement system including a first metal-organic framework (MOF) container is coupled downstream of the exhaust system, where the first MOF container is configured to capture a first gas species of the process effluent.

### CROSS-REFERENCE TO RELATED APPLICATIONS

This application claims the benefit of U.S. Provisional Application No. 63/674,193, filed on Jul. 22, 2024, and U.S. Provisional Application No. 63/676,332, filed on Jul. 27, 2024, which applications are hereby incorporated herein by reference.

### TECHNICAL FIELD

The present invention relates generally to a system and method for chemical processing, and, in particular embodiments, to a system and method for process chemistry abatement and/or recycling.

### BACKGROUND

Semiconductor manufacturing processes utilize various specialized gases to perform functions such as etching, deposition, and surface modification of silicon and other substrate materials. These processes occur within controlled environments known as process chambers, where precise gas mixtures, pressures, temperatures, and energy inputs are carefully managed to achieve desired results. After performing their intended functions, these process gases and their byproducts flow through exhaust systems and may be released to the environment or processed through general abatement systems.

In modern semiconductor fabrication, environmental considerations have become increasingly important as the industry works to reduce its ecological footprint. Many process gases used in semiconductor manufacturing may have various environmental impacts when released to the atmosphere. These concerns must be balanced with technical requirements, as the specific chemical properties of certain gases make them particularly effective for achieving precise manufacturing outcomes.

### SUMMARY

In accordance with one aspect of the present invention, a processing system is provided comprising a process chamber configured to process a substrate, an exhaust system coupled to the process chamber and configured to remove process effluent from the process chamber, and an abatement system comprising a first metal-organic framework (MOF) container coupled downstream of the exhaust system, wherein the first MOF container is configured to capture a first gas species of the process effluent.

In accordance with another aspect of the present invention, a processing system is provided comprising an abatement system comprising a first metal-organic framework (MOF) container configured to capture a first gas species of a process effluent received from a process chamber, and a recycling system configured to couple to the first MOF container. The recycling system comprises an extraction pump configured to create a pressure gradient to extract MOF captured gases comprising the first gas species from the first MOF container, and a purification system coupled downstream of the extraction pump and configured to increase concentration of the first gas species in the MOF captured gases.

In accordance with yet another aspect of the present invention, a method of operating a processing system is provided comprising introducing process gases into a process chamber of the processing system, processing a substrate in the process chamber using the process gases, directing process effluent from the process chamber through a multi-stage filtration system wherein the multi-stage filtration system removes reaction byproducts from the process effluent, and capturing a first gas species from the process effluent using a first metal-organic framework (MOF) container.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a schematic view of a processing system with an integrated abatement system comprising a plurality of MOF containers, in accordance with an embodiment;

FIGS. 2A-2B illustrate schematic views of processing systems with alternative rough pump positioning, in accordance with various embodiments;

FIGS. 3A-3B illustrates cross-sectional views of MOF container structure with granular material and support components, in accordance with an embodiment;

FIG. 4 illustrates a schematic view of a recycling system coupled to the abatement system for gas extraction and purification, in accordance with an embodiment;

FIGS. 5A-5C illustrate different schematic views of exhaust system, in accordance with various embodiments;

FIG. 6 illustrates a process flow diagram for operating the processing system of FIG. 1, in accordance with an embodiment;

FIG. 7 illustrates a process flow diagram for operating the processing system of FIGS. 2A-2B, in accordance with an embodiment; and

FIG. 8 illustrates a detailed process flow diagram for recycling and regeneration operations, in accordance with an embodiment.

### DETAILED DESCRIPTION OF ILLUSTRATIVE EMBODIMENTS

Semiconductor manufacturing processes, particularly dry etching processes, rely on process gases that deliver optimal performance and efficiency. As an etching gas, sulfur hexafluoride (SF₆) has demonstrated 10-100 times greater silicon (Si) etching efficiency compared to alternative fluorine-containing gases, enabling faster processing speeds and higher throughput. Additionally, SF₆ is chemically inert, non-toxic, and provides excellent process stability with consistent, reproducible results. These characteristics make SF₆ the choice for critical etching applications in advanced semiconductor manufacturing. However, SF₆ presents environmental challenges that have prompted exploration of alternative gases. Conventional approaches focus on developing replacement gases such as COF₂, but these alternatives come with multiple drawbacks. For example, COF₂ is corrosive, toxic, and presents substantial health hazards. Furthermore, COF₂ may be approximately 20 times more expensive than SF₆, and may provide lower throughput but with more gas consumption, substantially increasing manufacturing costs. Similar challenges exist for the dry etching of silica, silicon nitride, etc. where optimal process gases have included but are not limited to NF₃, CF₄, and CHF₃, all of which present environmental challenges, and despite not having known toxicity concerns, CF₄ is at risk for being labeled PFAS since it is a fully fluorinated carbon atom. Similar common process gas molecules at risk for being labeled PFAS include but are not limited to C₂F₆ and C₄F₈.

Embodiments of the disclosure provide systems and methods for capturing, abating, and recycling process chemistry gases used in semiconductor manufacturing. In various embodiments, a metal organic framework (MOF) structure may be strategically integrated into the exhaust pathway of a processing system to selectively capture specific gas molecules based on their size. In various embodiments, the MOF may be designed with precisely tunable pore sizes that can capture target molecules such as SF₆ (approximately 550 picometers in size) while allowing smaller molecules like nitrogen (N₂, approximately 350 picometers) to pass through. This selective capture mechanism may operate primarily through physisorption rather than chemisorption, enabling the subsequent extraction and recycling of the captured gases.

In one or more embodiments, the system may include specialized valve arrangements that allow for the continuous operation of the semiconductor processing equipment when the captured gases are extracted, or MOF components are replaced. In various embodiments, the system may incorporate pressure control mechanisms, including throttle valves, positioned to maintain optimal pressure conditions within the MOF region for effective gas capture. The captured gases may be extracted from the MOF in a controlled environment, purified, and potentially regenerated for reuse in the same or similar semiconductor processes.

In various embodiments, the system may achieve high collection efficiency, for example, over 99.9% efficiency for process gases like SF₆, dramatically reducing environmental impact while maintaining the high technical performance these gases provide. Unlike alternative approaches that require compromising on process performance or incurring substantial development costs, this solution preserves existing manufacturing processes and their associated benefits. Furthermore, the parallel MOF container design ensures continuous manufacturing operations without downtime for abatement system maintenance.

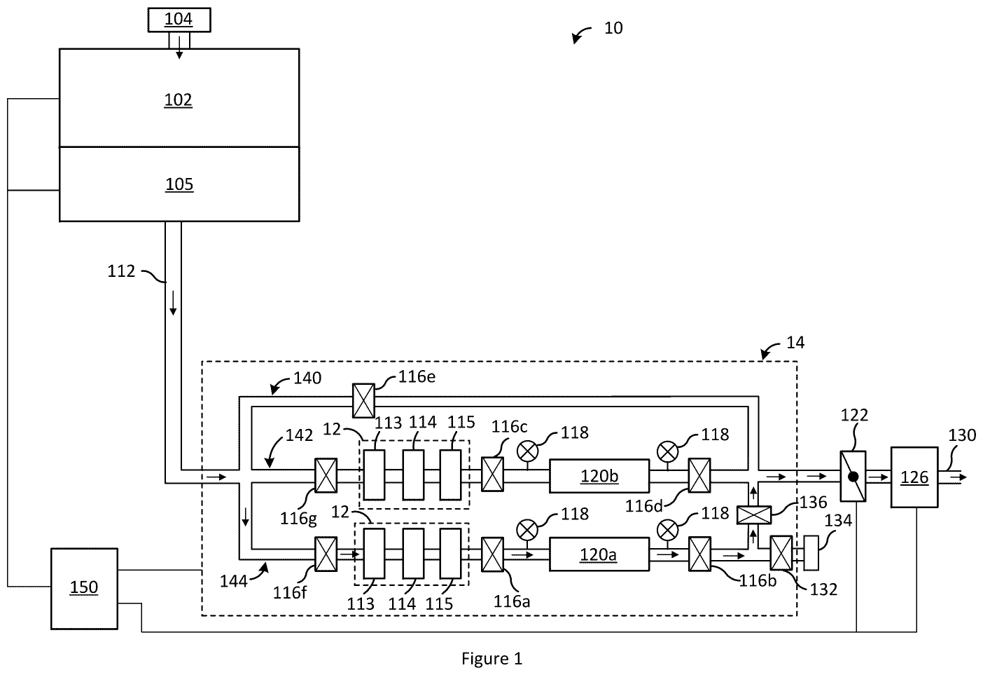

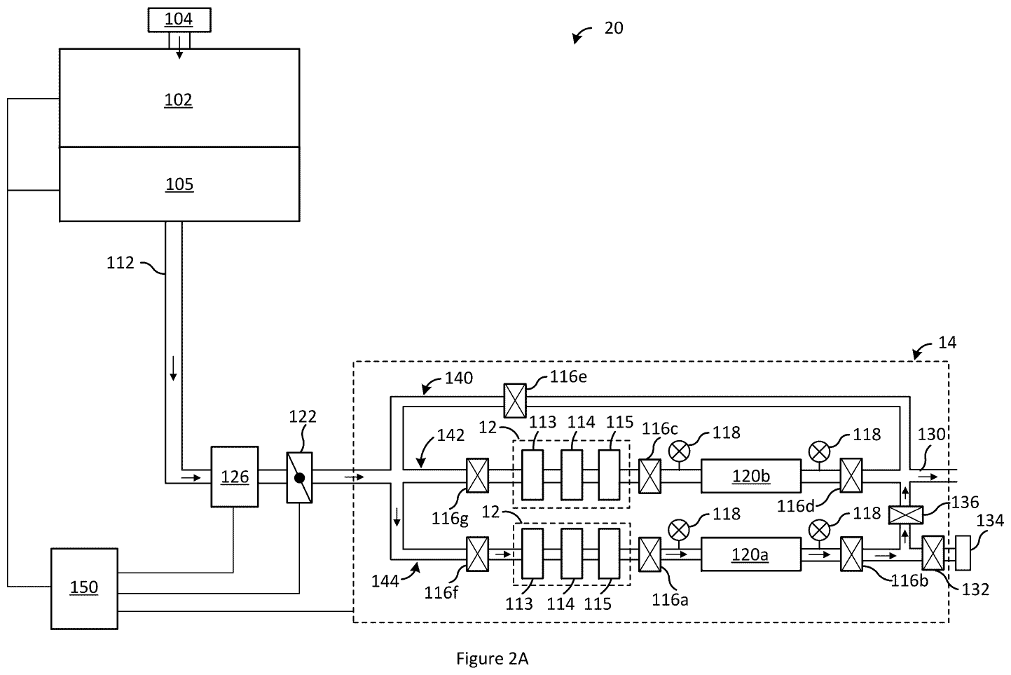

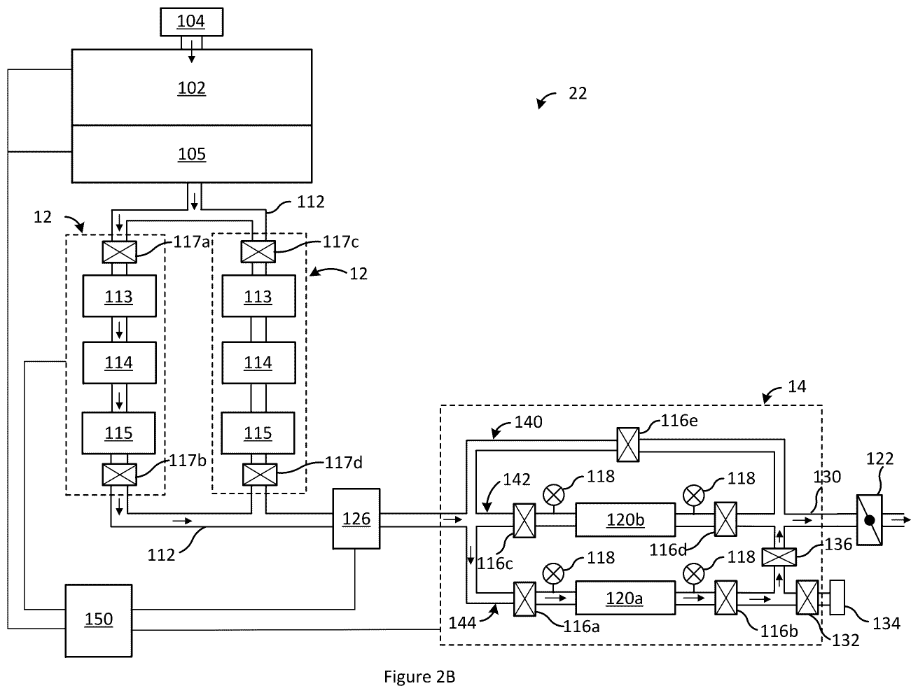

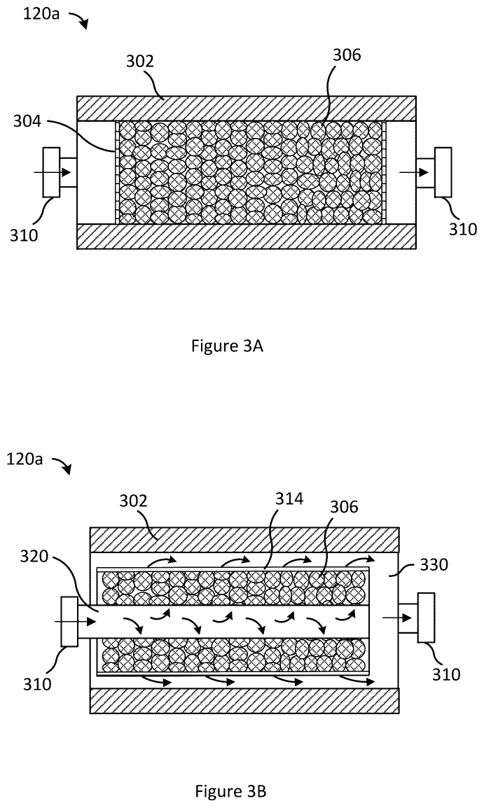

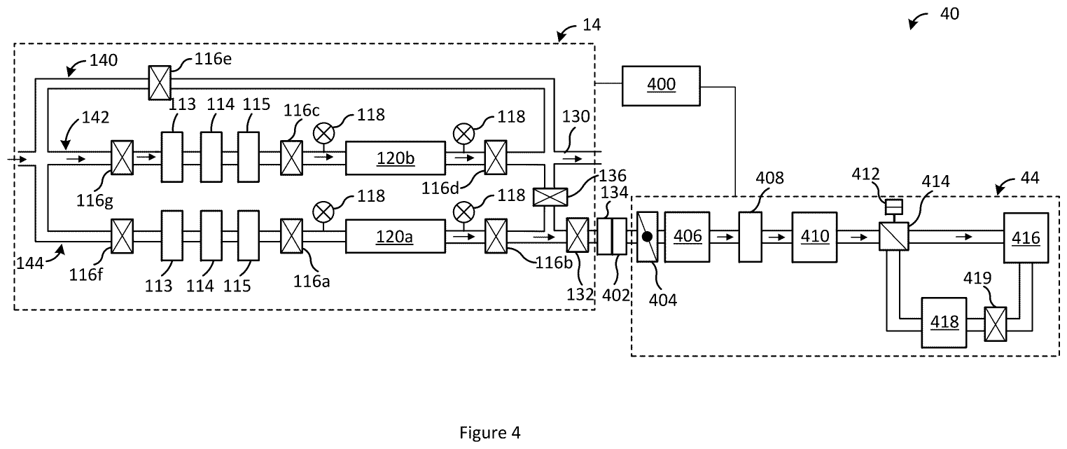

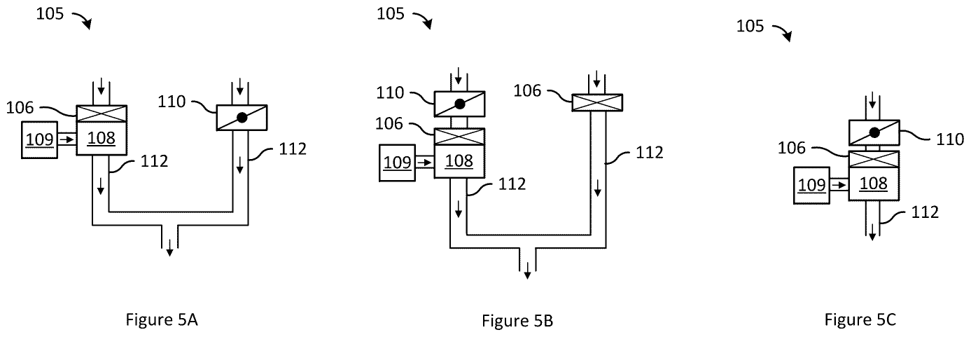

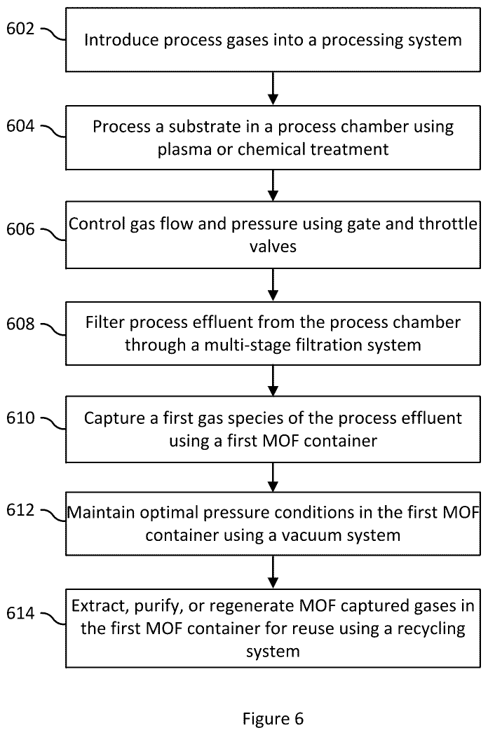

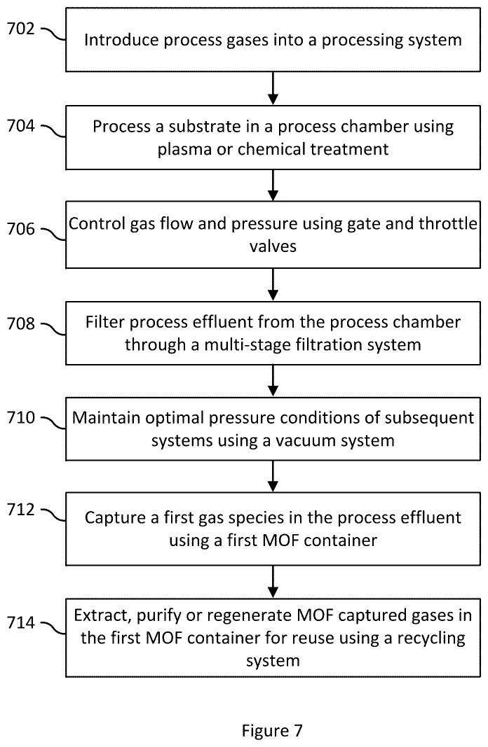

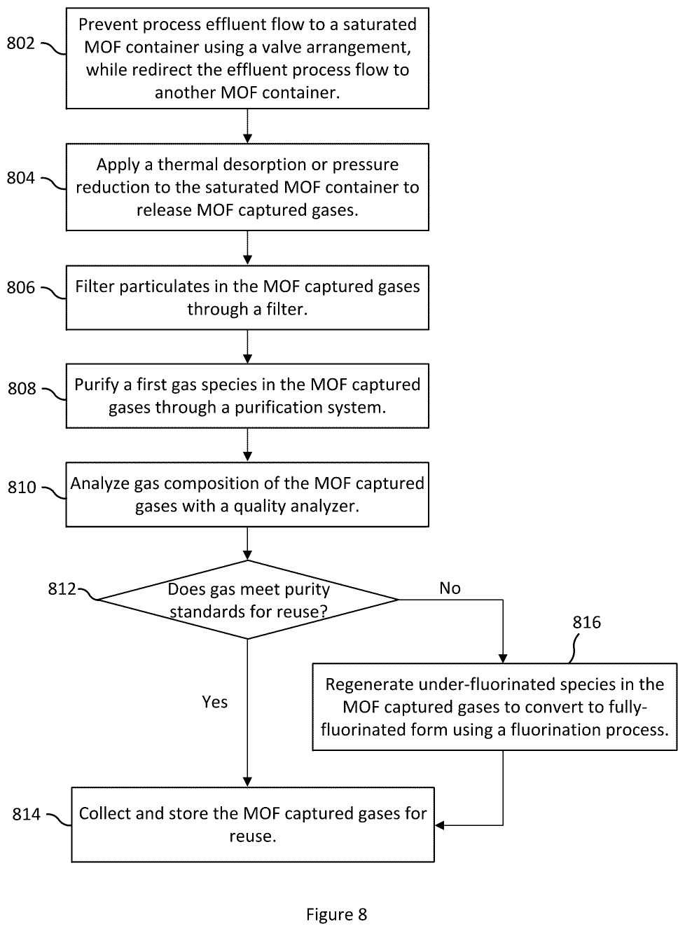

Embodiments of the disclosure are described in the context of the accompanying drawings. An embodiment of a processing system with an integrated abatement system comprising a plurality of MOF containers is described using FIG. 1. Variations of the processing system with alternative rough pump positioning are shown in FIGS. 2A-2B. Cross-sectional view of two MOF container structures with granular material and support components are illustrated in FIGS. 3A-3B. An embodiment of a recycling system coupled to the abatement system for gas extraction and purification is described using FIG. 4. Embodiments of the exhaust system is illustrated in FIGS. 5A-5C. Process flow diagrams for operating the processing systems are illustrated in FIGS. 6 and 7. A detailed process flow diagram for the recycling and regeneration operations is shown in FIG. 8.

FIG. 1 illustrates a processing system 10 with an integrated abatement system for capturing and managing process effluent gases, in accordance with an embodiment.

In various embodiments, the processing system 10 may comprise a process chamber 102 configured to process a substrate using various semiconductor manufacturing processes such as plasma etching or chemical treatment. A chemical supply system 104 may be coupled to the process chamber 102 and configured to supply process gases into the process chamber 102 for processing the substrate. In various embodiments, the process gases may include halogen-containing gases such as SF₆, NF₃, CF₄, CHF₃, or other fluorinated gases for etching applications. The process gases may also include hydrocarbons, chlorine-containing gases, bromine-containing gases, or other specialty gases used in semiconductor processing operations such as etching, deposition, or cleaning. Supplement gases such as nitrogen, argon, xenon, or helium may be used for chamber pressurization, dilution, or process control. In certain embodiments, oxygen (O₂) may be used as a supplement gas in oxide etching processes and may also impact the plasma chemistry by affecting how gases such as CF₄ or CHF₃ are broken down by the plasma. In some embodiments, the process gases may include SF₆ for silicon etching applications, along with supplement gases. In various embodiments, the chemical supply system 104 may supply process gases in their original molecular form for remote plasma configurations, where plasma generation may occur outside the process chamber 102 and reactive species may be transported into the chamber. In alternative embodiments, for direct plasma configurations, the chemical supply system 104 may supply molecular gases that are subsequently converted within the process chamber 102 into reactive species including radicals, ions, excited species, electrons, and other charged or neutral species through plasma generation within the chamber itself.

In one or more embodiments, the process chamber 102 may comprise a radio frequency (RF) source for generating plasma when plasma-based processing is performed. In various embodiments, the RF source may include inductively-coupled, capacitively-coupled, or waveguide-coupled plasma generation designs and may operate at radio frequencies such as 13.56 MHz or microwave frequencies such as 2.455 GHz. In some embodiments, the processing system 10 may operate at standard liters per minute (SLM) flow rates for process chemistry gases such as SF₆ and carrier gases such as N₂. In alternative embodiments, the processing system 10 may operate at flow rates less than 1000 sccm for process chemistry gases. In some embodiments, the flow rates may be less than 100 sccm. The carrier gas flow may or may not continue during processing operations, and there may or may not be a time delay between carrier gas shutoff after reaching target chamber pressure and the initiation of the plasma process. In some embodiments, additional RF or DC sources may be coupled to a substrate holder in the process chamber to apply bias powers to the substrate. In various embodiments, arrows or flow direction indicators as shown in FIG. 1 are included in the gas flow lines 112 to show the direction of process effluent flow through the processing system 10.

In various embodiments, an exhaust system 105 may be coupled to the process chamber 102 and configured to remove process effluent from the process chamber 102. In one or more embodiments, the process effluent may comprise various gas species including unreacted process gases such as SF₆, reaction byproducts such as silicon tetrafluoride (SiF₄), hydrogen fluoride (HF), partially radicalized (e.g., when process gas comprises SF₆) species SFₓ (x<6) such as SF₅ and SF₄, reactive fluorine species such as F and F₂, or the supplement gases described previously, such as nitrogen (N₂). In one or more embodiments, the process effluent may comprise both reaction byproducts and unreacted process gases, including gases such as SF₆ that may be captured and recycled for reuse.

In various embodiments, an exhaust system 105 may be coupled to the process chamber 102 and configured to remove process effluent from the process chamber 102. The exhaust system 105 may comprise various combinations of valves, pumps, and flow control components arranged in different configurations to meet specific processing requirements and pressure control needs. The exhaust system 105 may be designed to accommodate different pumping schemes including roughing pump only configurations, turbo pump assisted arrangements, or other vacuum system designs suitable for the particular semiconductor processing application.

As illustrated in FIGS. 5A-5C, the exhaust system 105 may be implemented in various configurations depending on the specific tool design requirements and processing conditions. FIGS. 5A and 5B show different parallel flow path configurations where multiple exhaust components provide separate routes from the process chamber 102, while FIG. 5C demonstrates a series arrangement, providing flexibility in system design to accommodate different processing requirements.

In some embodiments, as shown in FIG. 5A, the exhaust system 105 may comprise a gate valve 106 with turbo pump 108 in one flow path and a throttle valve 110 in a separate parallel flow path from the process chamber 102. The gate valve 106 may control flow through the turbo pump 108 to provide vacuum pumping capability, while the throttle valve 110 may provide an independent flow path for precise pressure control during processing operations.

In alternative embodiments, as illustrated in FIG. 5B, the exhaust system 105 may be configured with a different parallel arrangement where the throttle valve 110 and gate valve 106 are positioned in series within one flow path, while maintaining parallel routing options from the process chamber 102. Gas flow lines 112 may connect these components and direct the process effluent through the system, with the separate flow paths converging into a common gas flow line 112 downstream.

In certain embodiments, as represented in FIG. 5C, the exhaust system 105 may comprise a series arrangement where the gate valve 106, turbo pump 108, and throttle valve 110 are positioned sequentially along a single flow path from the process chamber 102. This simplified series configuration may be suitable for applications where a single controlled flow path meets the process requirements. In some embodiments, the exhaust system 105 may comprise only a direct connection from the process chamber 102 to the rough pump 126 without the turbo pump 108, gate valve 106, or throttle valve 110. In other embodiments, the exhaust system 105 may include various combinations of these valving components, such as only a throttle valve 110 or only a gate valve 106, depending on the specific process requirements and pressure control needs of the processing system 10.

In various embodiments, a nitrogen gas source 109 may be coupled to the turbo pump 108 illustrated in FIGS. 5A-5C for operational stability and to protect the turbo pump from reactive process gases and etch byproducts.

While FIGS. 5A-5C illustrate representative exhaust system configurations, additional arrangements may be implemented depending on specific processing requirements. In certain embodiments, the exhaust system 105 may comprise only a throttle valve and gate valve without a turbo pump, or may include these valves in alternative sequential arrangements. In some embodiments, a single adaptive pressure control (APC) valve may be included and serve dual functions, operating as both a gate valve for flow isolation and a throttle valve for pumping speed restriction by maintaining partially open positions. Various valve technologies may be employed within the exhaust system 105, including butterfly valves, louver-style valves, or other flow restriction mechanisms that provide different operational characteristics compared to traditional gate valves. The throttle valve functionality may be implemented using butterfly valve designs or similar louver-type mechanisms that offer variable flow restriction capabilities distinct from gate valve operation. The specific valve configuration and arrangement may be selected based on factors such as required pressure control precision, pumping speed requirements, process gas compatibility, and maintenance accessibility, while maintaining the core functionality of controlled process effluent removal from the process chamber 102.

In various embodiments, the processing system 10 may further comprise an abatement system 14 coupled downstream of the exhaust system 105 and configured to selectively capture a first gas species from the process effluent. In certain embodiments, the first gas species may be SF₆. In one or more embodiments, the abatement system 14 may comprise a plurality of metal-organic framework (MOF) containers arranged in parallel flow paths to enable continuous operation during maintenance and gas extraction operations. As illustrated in FIG. 1, the abatement system 14 may comprise a first MOF container 120a and a second MOF container 120b, though in various embodiments, additional MOF containers may be included to provide greater operational flexibility or increased gas capture capacity. In various embodiments, the parallel arrangement of MOF containers may prevent system downtime during MOF servicing operations by employing multiple MOF containers with associated valve arrangement as illustrated. The converged region where separate gas streams from the gate valve 106 and throttle valve 110 converge may provide an optimal location for integrating the MOF containers within the exhaust pathway. In certain embodiments, the abatement system 14 may comprise one MOF container such as the first MOF container 120a.

In various embodiments, the abatement system 14 may comprise a valve arrangement configured to direct the process effluent through selected MOF containers while closing process effluent flow through others. In one or more embodiments, the valve arrangement may comprise a first upstream valve 116a positioned upstream of the first MOF container 120a, a first downstream valve 116b positioned downstream of the first MOF container 120a, a second upstream valve 116c positioned upstream of the second MOF container 120b, a second downstream valve 116d positioned downstream of the second MOF container 120b, and a bypass line valve 116e for controlling flow through a bypass line 140. In some embodiments, the abatement system 14 may comprise flow paths designated as a first processing line 144, a second processing line 142, and a bypass line 140 to provide multiple routing options for the process effluent. In certain embodiments, the bypass line 140 may provide an alternative flow path that allows the system to continue operating even when all MOF containers require maintenance or replacement, ensuring uninterrupted semiconductor processing operations. In some embodiments, the abatement system 14 may also include a flange 134 positioned downstream of the MOF containers to provide a connection point for coupling additional systems such as a recycling system to extract and reuse MOF captured gases from saturated MOF containers.

In an embodiment of operation, the first MOF container 120a may be selected for capturing the first gas species. In such embodiment, the first upstream valve 116a and first downstream valve 116b may be opened while the second upstream valve 116c, second downstream valve 116d, and bypass line valve 116e are closed. Additionally, valve 136 may be opened and valve 132 closed to direct process effluent flow through the first MOF container 120a while closing flow to the bypass line 140 and second MOF container 120b. This valve arrangement may enable selective operation of individual MOF containers.

In various embodiments, the abatement system 14 may comprise pressure sensors 118 positioned at various locations upstream and downstream of the MOF containers to monitor pressure conditions within the MOF containers. In one or more embodiments, the pressure sensors 118 may be configured to detect changes in pressure differential across the MOF containers, which may serve as an indicator of MOF saturation levels. In embodiments where the MOF container becomes saturated with captured first gas species, the available pore space in the MOF materials may decrease, leading to increased flow resistance and a corresponding change in the pressure differential between the upstream and downstream pressure sensors 118. When the pressure differential change exceeds a predetermined threshold, this indicates that the MOF container has reached saturation and is ready for gas extraction or replacement.

In various embodiments, the abatement system 14 may further comprise multi-stage filtration systems 12 positioned upstream of the first or the second MOF container 120a or 120b, and configured to remove reaction byproducts from the process effluent before it reaches MOF containers. In one or more embodiments, the multi-stage filtration system 12 may comprise multiple sequential filtration stages, each designed to remove specific contaminants that may potentially damage or interfere with the operation of downstream MOF containers.

In some embodiments, the multi-stage filtration system 12 may comprise a filter 113, a neutralizer 114, or a fluorine species remover 115. In one or more embodiments, the filter 113 may be configured as a first filtration stage to physically remove silicon tetrafluoride (SiF₄) or particulates from the process effluent. In various embodiments, the filter 113 may comprise a stainless steel gauze or porous media designed to capture heavy particles, condensable, and solid reaction byproducts generated during the semiconductor processing operations. The filter 113 may include cooling coils to remove additional condensable and lower gas temperature before subsequent filtration stages. This physical filtration stage may prevent particulate matter from reaching downstream components and protect the integrity of subsequent filtration media.

In various embodiments, the neutralizer 114 may be positioned downstream from the filter 113 and configured as a second filtration stage to neutralize acidic gases such as hydrogen fluoride (HF), hydrogen chloride (HCl), or hydrogen sulfate (H₂SO₄) present in the process effluent. In some embodiments, the neutralizer 114 may comprise a soda lime media (e.g., sodium hydroxide and calcium oxide) or similar alkaline material that chemically reacts with HF to neutralize its corrosive properties. The soda lime material may neutralize approximately 10-15% of its weight in HF, providing effective protection against corrosive species. This neutralization stage may protect downstream components from the highly corrosive effects of HF, which can form when free fluorine species react with trace amounts of water vapor in the system.

In one or more embodiments, the fluorine species remover 115 may be positioned downstream from the neutralizer 114 and configured as a third filtration stage to contain and remove reactive fluorine species such as F and F₂ from the process effluent. The fluorine species remover 115 may comprise a sodium thiosulfate-based media or similar reducing agent that operates through acid-base neutralization processes to capture fluorine species while allowing target gases to pass through. In certain embodiments, the sodium thiosulfate-based media may also be configured to capture partially fluorinated species such as SF₄ and SF₅. In some embodiments, SF₆ may also be captured by the sodium thiosulfate-based media. This broader capture capability may provide additional protection for downstream MOF containers from partially fluorinated compounds.

In various embodiments, the sodium thiosulfate-based media may be packaged in a manner similar to the soda lime media described for the neutralizer 114, utilizing appropriate containment and flow distribution structures to maintain effective gas contact while preventing media migration. In alternative embodiments, the fluorine species remover 115 may replace the neutralizer 114 entirely, providing a single-stage approach for capturing both HF and other fluorine species depending on the specific process effluent composition.

In certain embodiments, the sodium thiosulfate-based media may be packaged with anti-clogging and pressure drop prevention measures similar to those described for the MOF granular material, since the sodium thiosulfate media may comprise crystalline powder material of micron-sized crystals that could present similar flow challenges when vacuum pumping is applied. The media may be combined with binders, flow aids, or support structures to maintain proper gas permeability while preventing the formation of flow restrictions or blockages that could impede system operation. This stage may ensure that primarily the target gas species, such as SF₆, along with inert carrier gases like nitrogen, reach the downstream abatement system.

In alternative embodiments, the order of the neutralizer 114 and fluorine species remover 115 may be switched within the multi-stage filtration system 12. In certain embodiments, the fluorine species remover 115 may be positioned downstream from the filter 113 and upstream of the neutralizer 114 to remove reactive fluorine species such as F and F₂ before HF neutralization occurs. This alternative ordering may be advantageous in situations where residual free fluorine species remaining after initial HF neutralization could subsequently react with trace amounts of water vapor in the system to form additional HF downstream of the neutralizer 114. By removing free fluorine species before the neutralization stage, the fluorine species remover 115 may prevent the reformation of HF and ensure more complete removal of corrosive species from the process effluent. The selection of component ordering may depend on specific process conditions, the relative concentrations of HF and free fluorine species in the process effluent, and the moisture content of the gas stream.

In various embodiments, additional upstream valves 116f and 116g may be positioned at the inlet of each parallel multi-stage filtration system 12 to provide enhanced control and isolation capabilities. Valve 116f may be positioned upstream of the multi-stage filtration system 12 in the first processing line 144, while valve 116g may be positioned upstream of the multi-stage filtration system 12 in the second processing line 142. These upstream valves may enable independent isolation of each filtration system for operations. In various embodiments, the upstream valves 116f and 116g may work in coordination with other the upstream and downstream valves (e.g., 116a-116d) and bypass valve 116e to provide complete flow control through the parallel processing lines, allowing selective operation of individual filtration and MOF container combinations while maintaining continuous process capability through the alternative processing line.

While three specific filtration stages are illustrated in FIG. 1, the multi-stage filtration system 12 may include additional filtration components depending on the specific process chemistry and requirements. In various embodiments, the multi-stage filtration system 12 may include temperature control elements to manage exothermic neutralization reactions, pressure monitoring sensors to detect filter saturation or blockage, bypass lines for maintenance operations, or additional chemical scrubbers for removing other reactive species. In certain embodiments, the multi-stage filtration system 12 may also include molecular sieves for removing moisture, activated carbon filters for organic contaminants, or specialized media for capturing metal-containing compounds from metal etching processes.

In one or more embodiments, the multi-stage filtration system 12 may comprise a controlled venting capability to enable safe maintenance and replacement of filtration media. In some embodiments, a leak valve may be positioned upstream of the filtration components to allow controlled introduction of air or inert gas during maintenance operations. This venting arrangement may provide direct access to the rough pump 126 and facility exhaust system while bypassing the MOF containers, enabling safe purging of the filtration region before media replacement. The controlled air bleeding may serve multiple safety purposes, including reacting away any incompletely captured or neutralized species within the filtration media and ensuring that potentially hazardous materials are safely processed before system maintenance. In various embodiments, this venting process may be performed by opening the leak valve while maintaining pumping through the rough pump 126 and closing valves to the MOF containers, allowing the air to sweep through the multi-stage filtration system 12 and carry any residual reactive species to the facility exhaust system. This approach may be particularly important when dealing with filtration media that has captured reactive or hazardous species, ensuring safety during maintenance operations and preventing the release of captured contaminants during media replacement procedures.

In various embodiments, a throttle valve 122 may be coupled downstream of the MOF containers and configured to control the flow rate and pressure conditions within the MOF containers to optimize gas capture efficiency. In one or more embodiments, a rough pump 126 may be coupled downstream of the throttle valve 122 to provide the primary vacuum source for the abatement system 14 and maintain the pressure gradient that drives process effluent flow through the processing system. In various embodiments, the rough pump 126 may be positioned after the abatement system 14 to prevent the large flow rate of nitrogen that the rough pump bleeds into the system from diluting the first gas species and interfering with the selective capture function of the MOF containers. The positioning of the rough pump 126 downstream of the abatement system 14 may be advantageous because placing the MOF containers downstream of the rough pump may result in higher nitrogen flow (100-1000 times greater) through the MOF containers due to the N₂ that may be continuously bled into the rough pump during operation. Non-captured gas species, such as nitrogen and other gases that pass through the MOF containers without being adsorbed, may be extracted through a gas outlet 130 that connects to the facility exhaust system for safe disposal.

In various embodiments, the processing system 10 may further comprise a controller 150 coupled to various components throughout the system to monitor and control operational parameters. In one or more embodiments, the controller 150 may comprise a programmable logic controller, computer system, or other electronic control device with processing capabilities, memory, and input/output interfaces. In some embodiments, the controller 150 may be coupled to the process chamber 102, the exhaust system 105, various components within the multi-stage filtration system 12, various components within the abatement system 14, rough pump 126, throttle valve 122, or gas outlet 130 to provide comprehensive system control and monitoring.

In an example operation, the controller 150 may be configured to monitor a pressure differential between pressure sensors 118 positioned upstream and downstream of the MOF containers. The controller 150 may determine saturation of the first MOF container 120a based on a change in the pressure differential that indicates increased flow resistance due to reduced available pore space in the MOF material. When the change in the pressure differential exceeds a predetermined threshold, the controller 150 may automatically switch process effluent flow from the first MOF container 120a to the second MOF container 120b by controlling the appropriate valves in the valve arrangement. Additionally, the controller 150 may generate a notification indicating that the first MOF container 120a is ready for extraction of the first gas species, enabling maintenance personnel to couple the saturated container to a recycling system for gas recovery operations.

In various embodiments, the controller 150 may also control various other operations of different components within the processing system 10 to optimize overall system performance. In various embodiments, the controller 150 may control the rough pump 126 to adjust vacuum levels and thereby control pressure conditions inside the MOF containers to optimize gas capture efficiency. The controller 150 may regulate flow rates through the multi-stage filtration system 12 by controlling the nitrogen gas source 109, turbo pump 108, and throttle valve 110 to maintain optimal gas velocities and residence times for effective filtration and subsequent MOF adsorption. In additional embodiments, the controller 150 may coordinate the operation of various valves and pumps to maintain proper pressure gradients throughout the system, manage the timing of valve switching operations, and ensure that process effluent flows through the intended pathways while maintaining the desired pressure and flow conditions for each system component.

FIG. 2A illustrates a variation 20 of the processing system shown in FIG. 1, where components sharing the same reference numbers have the same functions as described in FIG. 1. The primary difference in FIG. 2A is the positioning of the rough pump 126, which may be coupled between the exhaust system 105 and the abatement system 14. In some embodiments, the throttle valve 122 may be coupled between the rough pump 126 and the abatement system 14.

This alternative configuration may provide certain advantages depending on specific system requirements. In some embodiments, positioning the rough pump 126 upstream of the abatement system 14 may enable higher pressure operation within the MOF containers, which may enhance gas capture efficiency for certain MOF materials that perform better at elevated pressures. In some embodiments, the throttle valve 122 positioned between the rough pump 126 and abatement system 14 may allow for precise pressure control within the MOF region while maintaining the pumping capability provided by the rough pump 126. This arrangement may also provide more direct control over the pressure differential across the MOF containers, enabling fine-tuning of the capture conditions for optimal performance. In alternative embodiments, the rough pump 126 may be coupled inside the multi-stage filtration system 12, for example, between the neutralizer 114 and the fluorine species remover 115.

FIG. 2B illustrates a variation 22 of the processing system shown in FIGS. 1 and 2A, where components sharing the same reference numbers have the same functions as described in FIG. 1. The primary difference in FIG. 2B is the positioning of the multi-stage filtration system 12 upstream of both the abatement system 14 and the rough pump 126, creating a separate filtration stage that protects both the pump and the MOF containers from corrosive species. In this configuration, the multi-stage filtration system 12 may comprise parallel filtration paths, each including a filter 113, neutralizer 114, and fluorine species remover 115, with additional isolation valves 117a, 117b, 117c, and 117d positioned to provide enhanced control over individual filtration components.

The valve arrangement in FIG. 2B enables independent maintenance and replacement of filtration components within each parallel path. Valves 117a and 117c may be positioned upstream of the filtration systems, while valves 117b and 117d may be positioned downstream, allowing selective isolation of individual filtration paths for maintenance without disrupting the overall system operation. This configuration provides the same parallel operation benefits for the filtration system as the MOF containers, ensuring continuous processing capability even during filtration system maintenance.

In certain embodiments where the rough pump 126 is protected by upstream filtration as shown in FIG. 2B, the nitrogen gas flow typically bled into the rough pump 126 may be reduced or eliminated, since the pump no longer requires nitrogen protection from corrosive process gases. This reduction in nitrogen flow (e.g., 0.05 SLM to 5 SLM of process gas compared to 50 SLM) may enable the MOF containers in the abatement system 14 to operate with improved efficiency, as the reduced nitrogen dilution may preserve the MOF selectivity advantage and prevent the MOF material from becoming saturated with nitrogen rather than target gas species.

In some embodiments, the throttle valve 122 may be coupled downstream of the abatement system 14 to provide precise flow control and pressure regulation for the MOF containers, ensuring optimal operating conditions for gas capture efficiency.

In alternative embodiments, the fluorine species remover 115 may be positioned downstream of the rough pump 126, particularly when the fluorine species are determined to be non-damaging to the pump operation. This positioning may allow for the use of larger quantities of fluorine removal media without the need to pump process gases through the media, potentially improving the efficiency and capacity of the fluorine species removal process. The selection of fluorine species remover 115 positioning may depend on the specific fluorine species concentrations, the pump's tolerance to these species, and whether adequate pump protection is provided by the nitrogen gas flow into the pump or by upstream filtration components.

FIG. 3A illustrates a cross-sectional view of the first MOF container 120a, which may be representative of other MOF containers in the abatement system 14, in accordance with an embodiment. In various embodiments, the first MOF container 120a may comprise a cylindrical chamber with a chamber wall 302 that may be constructed from stainless steel or other corrosion-resistant materials suitable for handling reactive process gases and maintaining vacuum conditions. The chamber wall 302 may provide structural integrity and chemical compatibility with the process effluent and captured gas species.

In various embodiments, a support structure 304 may be disposed within the cylindrical chamber and configured to support the MOF material while allowing gas flow through the MOF container. In one or more embodiments, the support structure 304 may comprise a mesh, perforated plate, or porous media with specific hole sizes designed to retain the MOF granular material while minimizing flow resistance. The hole sizes in the support structure 304 may be selected to prevent MOF particles from escaping while maintaining adequate gas permeability for efficient capture operations.

In various embodiments, MOF granular material 306 may be disposed within the cylindrical chamber and supported by the support structure 304. The MOF granular material 306 may comprise metal organic frameworks, which are porous polymers composed of metal clusters and organic ligands designed with tunable pore sizes to selectively capture molecules of specific sizes while allowing differently sized molecules to pass through. In certain embodiments, the MOF material may be configured to capture molecules such as SF₆ (approximately 550 picometers in size) while allowing smaller process gases such as N₂ (approximately 350 picometers) to move through the MOF region without being captured. The MOF material may also capture SF₅ and SF₄, which are similar in size to SF₆, while still allowing smaller molecules like N₂, F, and F₂ to pass through. In some embodiments, the MOF may be designed specifically for the target gas species intended to be captured, for example, the first gas species described previously, where the exact MOF composition may be determined using modeling approaches based on operating parameters such as molecular chemistry, relative quantity, flow rate, pressure, and temperature. In some embodiments, the capturing mechanism of MOF material may operate primarily through physisorption rather than chemisorption, enabling subsequent extraction and recycling of the captured gases. In some embodiments, the plurality of MOF containers may comprise an optimized pressure for the MOF granular materials 306 to capture the first gas species such as SF₆.

In various embodiments, the MOF materials may comprise zirconium-based frameworks such as UiO-66 variants, copper-based frameworks such as HKUST-1 variants, aluminum-based frameworks such as MIL-100 or MIL-101, chromium-based frameworks, zinc-based frameworks, or zeolitic imidazolate frameworks (ZIFs) such as ZIF-8 or ZIF-67. In various embodiments, the MOF granular material 306 may comprise additional materials such as polymeric binders to enhance mechanical strength and prevent clumping during operation. The binders may help maintain the structural integrity of the granular material under pressure cycling and gas flow conditions while preserving the selective adsorption properties of the MOF. In some embodiments, the MOF granular material 306 may also comprise materials to prevent clogging and minimize pressure drops during operation.

The high selectivity provides substantial advantages for the MOF-based abatement system compared to alternative approaches such as substituting SF₆ with other process gases like COF₂. The MOF-based approach enables continued use of SF₆ while achieving reduced environmental impacts. In some embodiments, the system may capture greater than 99.9% of SF₆ molecules, meaning no more than 1 in 1000 molecules are released to the environment. In contrast, alternative gases like COF₂, while having lower inherent environmental impact, require 10-100 times more gas consumption due to lower silicon plasma etch efficiency (0.1-0.01 compared to SF₆'s normalized efficiency of 1). Additionally, COF₂ presents safety concerns as it is corrosive, toxic, and poses health hazards, while SF₆ remains chemically inert. The economic advantages are also significant, as COF₂ costs approximately 20 times more than SF₆, and switching to alternative gases would result in dramatically decreased throughput, less ideal etch profiles, and substantial development costs. The MOF-based abatement system therefore provides a pathway to maintain the superior technical and economic performance of SF₆ while addressing environmental concerns through highly efficient gas capture and recycling.

In one or more embodiments, flanges 310 may be coupled to opposing ends of the cylindrical chamber to enable removable connection to the gas flow lines and facilitate replacement or servicing of the MOF container. Other MOF containers in the abatement system, such as the second MOF container 120b, may have similar construction and components as described for the first MOF container 120a. In various embodiments, the container size and flange size may be selected based on specific application requirements, flow rates, and system integration needs. In various embodiments, basic valves may be positioned between each container element to enable independent replacement or maintenance of individual MOF containers without affecting the operation of other system components.

FIG. 3B illustrates an alternative embodiment of the first MOF container 120a in a canister configuration, in accordance with an embodiment. Components and features in FIG. 3B that share reference numbers with those in FIG. 3A have corresponding structures and operations as previously described.

In various embodiments, a support structure 314 may be disposed within the cylindrical chamber and configured to support the MOF material while allowing gas flow through the container. In some embodiments, the support structure 314 may comprise multiple layers or sections with perforated plates or mesh structures designed to distribute gas flow evenly throughout the MOF granular material 306. In some embodiments, the support structure 314 may separate the container into distinct zones, including an inlet zone 320 where process effluent enters the container and an outlet zone 330 where filtered gases exit the container. The arrows in FIG. 3B indicate the gas flow path through the support structure 314, showing how process effluent may be directed from the inlet zone 320, through the MOF material, and into the outlet zone 330 for optimal capture efficiency. The canister configuration shown in FIG. 3B may increase the contact area between the process effluent and the MOF granular material 306, potentially improving capture efficiency and reducing the residence time required for effective gas adsorption.

In some embodiments, a heating element may be coupled to the chamber wall 302 to control temperature inside the cylindrical chamber. In various embodiments, the heating element may enable thermal desorption of captured gas species when the MOF container requires regeneration or gas extraction operations, and may also help optimize capture efficiency by maintaining optimal operating temperatures for the MOF material during gas adsorption processes.

FIG. 4 illustrates a processing system 40 comprising a recycling system, in accordance with one embodiment. Components and features in FIG. 4 that share reference numbers with those in FIG. 1 have corresponding structures and operations as previously described.

In various embodiments, a recycling system 44 may be removably coupled to the abatement system 14 through a coupling connection between flange 402 and flange 134. The recycling system 44 may be configured to extract, purify, or regenerate MOF captured gases from saturated MOF containers for reuse in semiconductor processing operations. In various embodiments, when the recycling system 44 is coupled to the abatement system 14 for gas extraction operations, the first upstream valve 116a and valve 136 may be closed while the second upstream valve 116c and second downstream valve 116d may be opened to direct the process effluent flow through the second MOF container 120b. The valve 132 may be opened to allow MOF captured gases to flow from the saturated first MOF container 120a into the recycling system 44. This valve switching method may enable gas extraction and recycling operations without affecting the ongoing semiconductor manufacturing process flow.

In various embodiments, the recycling system 44 may comprise an extraction pump 406 configured to create a pressure gradient to extract MOF captured gases from the saturated MOF container. A throttle valve 404 may be positioned upstream of the extraction pump 406 to control a flow rate of the MOF captured gases during the extraction process. In various embodiments, the extraction pump 406 may operate by creating a pressure differential that induces desorption of the captured gas species from the MOF material through physisorption release mechanisms. In some embodiments, a thermal treatment may be applied to the saturated first MOF container 120a to enhance the desorption of MOF captured gases, where heating elements or thermal control systems increase the temperature of the MOF material to facilitate the release of adsorbed gas species through thermal desorption mechanisms.

In some embodiments, a filter 408 may be coupled downstream of the extraction pump 406 and configured to remove particulates from the MOF captured gases that may have been released during the extraction process. In some embodiments, a purification system 410 may be coupled downstream of the filter 408 and configured to increase concentration of the first gas species in the MOF captured gases by removing impurities and separating target molecules from other gas components through techniques such as molecular separation, selective adsorption, or chemical purification processes. In various embodiments, the first gas species concentration in the MOF captured gases may be increased after treatment from the purification system 410.

In various embodiments, a gas spectrometer 412 may be coupled downstream of the purification system 410 and configured to measure gas composition of the MOF captured gases and generate composition data indicating purity levels of the first gas species. In one or more embodiments, the gas spectrometer 412 may operate using analytical techniques such as mass spectrometry, gas chromatography, or infrared spectroscopy to determine the concentration and purity of specific gas species (e.g., the first gas species that may be captured by MOF). In various embodiments, the gas spectrometer 412 may include gas sensors or detectors to identify the gas species and calculate concentration based on signal intensity. In one embodiment, the gas sensors may measure infrared absorption spectra to determine molecular identity, as different gas molecules absorb infrared radiation at characteristic wavelengths specific to their molecular structure. In some embodiments, the gas spectrometer 412 may also comprise processing algorithms that analyze molecular composition and calculate purity percentages based on detected gas concentrations. In some embodiments, the gas spectrometer 412 may generate electrical signals or data corresponding to the measured gas composition, which may be transmitted to control systems (e.g., a controller 400) for decision-making purposes.

In various embodiments, a distribution valve 414 may be coupled to the gas spectrometer 412 and configured to receive control signals from the gas spectrometer 412 based on the measured composition data. In some embodiments, the distribution valve 414 may operate as a switching valve that directs the MOF captured gases along different pathways depending on whether the purity levels of the first gas species meet predetermined requirements. When the composition data indicates that the first gas species meets predetermined purity requirements, the distribution valve 414 may direct the gases to a storage container 416 for reuse. When the purity requirements are not met, the distribution valve 414 may direct the gases to a regeneration system 418 for further processing.

In various embodiments, the regeneration system 418 may be configured to convert under-fluorinated species such as SF₄ and SF₅ to their fully-fluorinated form SF₆ through a fluorination process. In one or more embodiments, the regeneration system 418 may include components such as a reaction chamber, a fluorine gas source for supplying F₂ gas, a power source for generating plasma or providing energy for the fluorination reactions, electrodes or RF coupling systems for plasma generation, and temperature control systems. In some embodiments, the regeneration process may involve exposing the under-fluorinated species to fluorine radicals or F₂ gas in the presence of electrons or plasma to facilitate the addition of fluorine atoms and convert SF₄ and SF₅ back to SF₆. In various embodiments, when the regeneration system 418 completes the conversion of under-fluorinated species to their fully-fluorinated form, valve 419 may be opened to direct the regenerated gases to the storage container 416 for reuse in semiconductor processing operations.

In various embodiments, once regenerated, the MOF material may be reused for thousands of adsorption and desorption cycles, potentially exceeding 10,000 cycles under optimal operating conditions. However, if reactive species such as HF or free fluorine radicals breakthrough the multi-stage filtration system and reach the MOF containers, these species may damage the MOF structure through chemisorption or chemical degradation. When such breakthrough occurs, the MOF material may lose adsorption capacity over time and replacement with new MOF material may be performed to maintain system performance.

In some embodiments, the regeneration process described above may be particularly effective for sulfur-containing compounds because the sulfur in SF₆ is not consumed during the etching process, as the primary etch byproduct may be SiF₄ in silicon etching applications. Since the sulfur is conserved, any partially fluorinated sulfur species SFₓ where x=0-5 may be regenerated back to SF₆ in a substantially closed-loop system, though the process may not achieve 100% efficiency, provided the species were reversibly captured by the MOF through physisorption mechanisms.

While the regeneration system 418 is described in the context of converting under-fluorinated species SF₄ and SF₅ to SF₆, the regeneration system 418 is not limited to sulfur fluoride compounds. In various embodiments, the regeneration system 418 may be applied to other gases such as NF₃, CF₄, CHF₃, and other halogenated compounds to convert partially reacted species back to their desired fully halogenated forms or to convert one type of halogenated compound to another type. For example, the regeneration system 418 may be configured to convert partially fluorinated carbon compounds such as CF₃ radicals back to CF₄, or to convert nitrogen fluoride species such as NF₂ back to NF₃ through appropriate halogenation processes using the corresponding halogen sources and reaction conditions.

In various embodiments, gas spectrometers similar to the gas spectrometer 412 may be positioned at multiple locations throughout the processing system 10 to monitor gas composition and optimize system performance. In some embodiments, a gas spectrometer may be positioned upstream of the MOF containers to analyze the composition of process effluent before gas capture, enabling real-time monitoring of target gas concentrations and adjustment of system parameters for optimal capture efficiency. In additional embodiments, a gas spectrometer may be positioned downstream of the MOF containers to verify capture effectiveness and monitor breakthrough of target gas species, providing feedback for determining when MOF containers require regeneration or replacement.

In certain embodiments, gas spectrometers may be positioned between different stages of the multi-stage filtration system 12 to monitor the effectiveness of individual filtration components and determine optimal media quantities and replacement schedules. In some embodiments, gas spectrometers may be installed at monitoring locations, such as immediately upstream of the MOF containers, to provide continuous monitoring throughout the operational lifetime of the system in manufacturing facilities. Such monitoring installations may generate alarms when contaminant levels exceed predetermined thresholds, indicating that breakthrough of damaging species through the multi-stage filtration system 12 may be occurring and that filtration media replacement or system maintenance is required to protect the downstream MOF containers.

In certain embodiments, a gas spectrometer may be positioned in the recycling system after extraction from the MOF containers but before the purification system, particularly when the purification system may not be necessary for certain applications. This positioning enables direct assessment of the purity of extracted gases, allowing the system to determine whether the MOF captured gases can be used directly without additional purification, or whether purification processing is required. When the gas spectrometer indicates that extracted gases meet predetermined purity standards, the purification system may be bypassed, and the gases may be directed directly to storage or reuse applications, improving gas consumption efficiency.

In various embodiments, the processing system 40 may further comprise a controller 400 coupled to various components of the recycling system 44 and the abatement system 14 to coordinate the valve operations for the extraction, purification, analysis, and regeneration operations based on system requirements and measured parameters. In one or more embodiments, the controller 400 may comprise a programmable logic controller, computer system, or other electronic control device with processing capabilities, memory, input/output interfaces, and communication modules for interfacing with various sensors, valves, and system components.

In exemplary embodiments, the controller 400 may be programed to monitor gas composition data from the gas spectrometer 412, where the data may include concentration levels of specific gas species such as SF₆, SF₅, SF₄, nitrogen, and other impurities, along with purity percentages and molecular identification information. The controller 400 may control the distribution valve 414 to direct the MOF captured gases by opening a first flow path to the storage container 416 when the purity of the first gas species in the MOF captured gases exceeds a predetermined purity threshold, such as 95% or higher SF₆ concentration.

In another exemplary embodiment, when the measured purity of the first gas species in the MOF captured gases falls below the predetermined threshold, the controller 400 may control the distribution valve 414 to close the flow path to the storage container 416 and open a second flow path to direct the MOF captured gases to the regeneration system 418. The controller 400 may then control operational parameters of the regeneration system 418, including regulating the supply of fluorine species such as F₂ gas flow rates, controlling power levels supplied to plasma generation equipment for creating fluorine radicals, managing temperature control systems to maintain optimal reaction conditions, and adjusting pressure levels within the regeneration chamber to facilitate efficient conversion of under-fluorinated species to their fully-fluorinated forms.

In alternative embodiments, the recycling system 44 may be configured with different coupling arrangements to the MOF containers in the abatement system 14 depending on operational requirements and system configuration. In one embodiment, as illustrated in FIG. 4, the recycling system 44 may be removably coupled to the abatement system 14 through flange connections, allowing the recycling system to be connected when gas extraction is needed and disconnected during normal processing operations.

In other embodiments, particularly for configurations where MOF containers are positioned downstream of the rough pump (such as in FIGS. 2A-2B), the recycling system may be permanently integrated into the abatement system flow paths. In such configurations, T-junctions may be positioned in the gas flow lines downstream of the MOF containers but upstream of the downstream valves (such as valves 116b or 116d). These T-junctions may include additional valves and extraction pathways leading directly to extraction pumps and associated recycling components, enabling in-situ extraction of captured gases from one MOF container while the other MOF container remains operational in the main process flow.

In certain embodiments, the MOF containers may serve dual functions as both capture vessels and storage containers for the target gas species. In such configurations, the recycling system 44 may comprise a controlled release system configured to extract predetermined quantities of the MOF captured gases for reuse in processing operations. The controlled release system may include mass flow controllers and pressure regulation systems configured to maintain appropriate system pressures (such as approximately 30 psi) behind the flow controllers to enable precise dispensing of the captured gases back into the process chamber or gas supply system. This approach may be particularly advantageous when the same MOF container used for capture in the abatement system 14 can subsequently be relocated to the gas supply system for controlled gas delivery.

In various embodiments, the purification system 410 may be optional depending on the purity of the gases extracted directly from the MOF containers. When the MOF captured gases meet predetermined purity requirements for direct reuse, the recycling system may bypass purification stages and direct the extracted gases directly to storage or back to the process gas supply system. This simplified recycling approach may be particularly applicable when the multi-stage filtration system effectively removes contaminants upstream of the MOF containers, resulting in high-purity captured gases that require minimal additional processing before reuse.

FIG. 6 illustrates an operational flow diagram for operating the processing system described in FIG. 1, in accordance with an embodiment.

At block 602, process gases may be introduced into a processing system. The process gases may comprise halogen-containing gases such as SF₆, NF₃, CF₄, CHF₃, or other fluorinated gases for etching applications, as well as supplement gases as described with reference to the chemical supply system 104 in FIG. 1.

At block 604, a substrate may be processed in a process chamber using plasma or chemical treatment. In various embodiments, the substrate processing may be performed in the process chamber 102 as described with reference to FIG. 1, which may include a radio frequency (RF) source for generating plasma when plasma-based processing operations are performed. In some embodiments, the plasma source may include inductively-coupled, capacitively-coupled, or waveguide-coupled designs operating at radio frequencies such as 13.56 MHz or microwave frequencies such as 2.455 GHz.

At block 606, gas flow and pressure may be controlled using gate and throttle valves. The gas flow control may be implemented using the gate valve 106 and throttle valve 110 within the exhaust system 105 as described with reference to FIGS. 1 and 5A-5C, where the gate valve 106 may control gas flow from the process chamber 102 and the throttle valve 110 may provide precise pressure control within the chamber during processing operations.

At block 608, process effluent from the process chamber may be filtered through a multi-stage filtration system. In at least one embodiment, the filtration process may be performed using the multi-stage filtration system 12 as described with reference to FIG. 1, which may comprise a filter 113 for removing particulates, a neutralizer 114 for neutralizing HF, and a fluorine species remover 115 for containing reactive fluorine species. In some embodiments, the multi-stage filtration system may further comprise additional filtration components as described previously with reference to FIG. 1.

At block 610, a first gas species of the process effluent may be captured using a first MOF container in an abatement system. In various embodiments, the gas capture may be performed using the abatement system 14 as described with reference to FIG. 1, which may comprise MOF containers 120a and 120b with valve arrangements for directing process effluent flow. The MOF materials may selectively capture target gas species based on molecular size through physisorption mechanisms, as described with reference to FIGS. 3A-3B.

At block 612, optimal pressure conditions in the first MOF container may be maintained using vacuum systems. In one or more embodiments, the vacuum systems may comprise the rough pump 126 and throttle valve 122 as described with reference to FIG. 1, where the rough pump 126 may provide the primary vacuum source and the throttle valve 122 may control flow rates and pressure conditions within the MOF containers. In various embodiments, non-captured gas species in the process effluent may be extracted through a gas outlet that connects to the facility exhaust system for safe disposal.

At block 614, MOF captured gases in the first MOF container may be extracted, purified, or regenerated for reuse using a recycling system. The recycling operations may be performed using the recycling system 44 as described with reference to FIG. 4, which may include extraction pumps, purification systems, gas spectrometers, and regeneration systems for processing the captured gases and preparing them for reuse in processing operations.

FIG. 7 illustrates an operational flow diagram for operating the processing system described in FIGS. 2A-2B, in accordance with an embodiment. Blocks 702, 704, 706, 708, and 714 may be performed using similar processes and components as described with reference to blocks 602, 604, 606, 608, and 614 in FIG. 6, respectively. The primary difference from FIG. 6 is the sequence of vacuum system operation and gas capture, where the vacuum system may be operated before the gas capture step to establish optimal pressure conditions upstream of the MOF containers, as illustrated in the alternative system configuration of FIGS. 2A-2B.

At block 710, optimal pressure conditions of subsequent systems may be maintained using a vacuum system. In various embodiments, the vacuum system may comprise the rough pump 126 or throttle valve 122 coupled between the exhaust system 105 and the abatement system 14, as described with reference to FIGS. 2A-2B. This configuration may enable higher pressure operation within the MOF containers and provide more direct control over the pressure differential across the MOF containers compared to the arrangement shown in FIG. 1.

At block 712, a first gas species in the process effluent may be captured using a first MOF container. In some embodiments, the gas capture may be performed using the abatement system 14 as described with reference to FIGS. 2A-2B, where the first MOF container may operate at the controlled pressure conditions established by the upstream rough pump 126 and throttle valve 122. In certain embodiments, this arrangement may enhance gas capture efficiency for certain MOF materials that perform better at elevated pressures, while the throttle valve 122 positioned between the rough pump 126 and abatement system 14 allows for precise pressure control within the MOF region.

While not explicitly shown in the flowcharts of FIGS. 6-7, additional operations may be performed as described in the previous FIGS. 1-4. For example, pressure monitoring operations may be performed using pressure sensors 118 to detect MOF saturation levels, as illustrated in FIG. 1. Additionally, thermal treatment may be applied to MOF containers to enhance gas desorption during extraction operations, as described with reference to FIGS. 3A-3B. These operations may be implemented as needed based on specific system requirements and operational parameters. In various embodiments, the operational flow diagrams in FIGS. 6 and 7 may be conducted using the controller 150 as described with reference to FIGS. 1 and 2A-2B, which may coordinate the timing and sequencing of the various process steps and component operations.

FIG. 8 illustrates a detailed process flow diagram for recycling and regeneration operations, in accordance with an embodiment.

At block 802, process effluent flow to a saturated MOF container may be prevented using a valve arrangement, while the process effluent flow may be redirected to another MOF container. In various embodiments, this valve switching operation may be performed using the valve arrangement described with reference to FIG. 1, where valves such as 116a and 136 may be closed while valves 116c and 116d may be opened to redirect flow from the first MOF container 120a to the second MOF container 120b, ensuring continuous processing operations.

At block 804, thermal desorption or pressure reduction may be applied to the saturated MOF container to release MOF captured gases. In one or more embodiments, the gas extraction may be performed using methods described with reference to FIG. 4, where thermal treatment may be applied through heating elements coupled to the chamber wall 302 as described in FIGS. 3A-3B, or pressure differential may be applied using the extraction pump 406 to create a vacuum for gas desorption.

At block 806, particulates in the MOF captured gases may be filtered through a filter. In some embodiments, the filtration may be performed using the filter 408 as described with reference to FIG. 4, which may be positioned downstream of the extraction pump 406 to remove any particulates released during the extraction process.

At block 808, a first gas species in the MOF captured gases may be purified through a purification system. In one or more embodiments, the purification may be performed using the purification system 410 as described with reference to FIG. 4, which may increase concentration of the first gas species by removing impurities and separating target molecules from other gas components.

At block 810, gas composition of the MOF captured gases may be analyzed with a gas spectrometer. In some embodiments, the analysis may be performed using the gas spectrometer 412 as described with reference to FIG. 4, which may measure gas composition and generate composition data indicating purity levels of the first gas species using analytical techniques such as mass spectrometry or gas chromatography.

At block 812, a determination may be made based on whether the gas meets purity standards for reuse. In various embodiments, this decision may be based on the composition data generated by the gas spectrometer 412, where predetermined purity thresholds may be compared against the measured gas composition.

If the gas meets purity standards (Yes path), the process may proceed to block 814, where the MOF captured gases may be collected and stored. In some embodiments, the MOF captured gases may be compressed and stored in a storage container for reuse in additional processing (e.g., semiconductor processing). This storage operation may be performed using the storage container 416 as described with reference to FIG. 4.

In alternative embodiments, the MOF container itself may serve as the storage container, where the captured gases remain stored within the MOF material at sub-atmospheric pressure rather than being transferred to a separate pressurized storage vessel. In such embodiments, the MOF container may be removed from the exhaust line and repositioned within the gas supply system to enable direct delivery of the stored gases to the process chamber.

In certain embodiments when purity standards for MOF captured gases are not stringent, the captured species may be collected for direct reuse. In other embodiments, a gas spectrometer may be positioned upstream of the MOF containers to monitor the composition of gases entering the MOF, ensuring that only sufficiently pure gases are captured and stored. This upstream monitoring approach enables confidence that the gases stored within the MOF meet the required purity standards for subsequent reuse. Storing gases in MOF materials at sub-atmospheric pressure and subsequently delivering them to process chambers may provide safety advantages over traditional pressurized gas cylinders.

If the gas does not meet purity standards (No path), the process may proceed to block 816, where under-fluorinated species in the MOF captured gases may be regenerated to convert to fully-fluorinated form using a fluorination process. In various embodiments, the regeneration may be performed using the regeneration system 418 as described with reference to FIG. 4, which may include fluorine gas sources, plasma generation equipment, and temperature control systems to facilitate conversion of species such as SF₄ and SF₅ back to SF₆. After regeneration, the process may return to block 814 for storage of the regenerated gases.

While not explicitly shown in the flowchart of FIG. 8, additional operations may be performed as described in the previous FIGS. 1-4. For example, flange connection operations may be performed using flange 134 to couple the recycling system 44 to the abatement system 14, as described with reference to FIGS. 1 and 4. Temperature control operations may be implemented using heating elements coupled to the MOF container walls to enhance thermal desorption during gas extraction, as described with reference to FIGS. 3A-3B. Furthermore, pressure monitoring operations may be performed using pressure sensors 118 to optimize extraction conditions and confirm successful gas removal from the MOF containers. These operations may be implemented as needed based on specific recycling requirements, gas composition targets, and operational parameters. In various embodiments, the process flow diagram in FIG. 8 may be conducted using the controller 400 as described with reference to FIG. 4, along with coordination from the controller 150 described in FIGS. 1-3, which may manage the valve switching operations, extraction timing, quality analysis decisions, and regeneration process parameters.

In various embodiments, the processing system described in this disclosure may be configured to capture different gas species used sequentially in the same process chamber during different processing steps or recipes. For example, the parallel MOF container configuration may be utilized where one processing line is optimized for capturing a first gas species (such as SF₆) while the second processing line is optimized for capturing a second gas species (such as NF₃ or CF₄) that may be used in the same process chamber at different times. The valve arrangement may direct process effluent to the appropriate MOF container based on the specific gas chemistry being used in the current processing step, enabling selective capture and recycling of multiple valuable process gases from a single process chamber. This approach may be particularly advantageous in advanced semiconductor processing tools that utilize multiple gas chemistries in sequence for different etching or processing operations.

The principles and systems described herein may also be applied to other processing operations (e.g., plasma dicing) involving process gases beyond etching applications. In particular embodiments, the MOF-based capture and recycling system may be adapted for use with atomic layer deposition (ALD) precursors and other specialty gases used in deposition, cleaning, or surface modification processes. Many ALD precursors and specialty process gases represent significant material costs and may have environmental implications when released as waste, making them suitable candidates for capture and recycling using the selective adsorption capabilities of appropriately designed MOF materials. The system may be configured with MOF materials having pore sizes and chemical properties tailored to the specific molecular characteristics of these alternative process gases, extending the environmental and economic benefits of gas recycling beyond etching applications to the broader manufacturing process space.

While the inventive aspects are described primarily in the context of semiconductor manufacturing processes using SF₆ for silicon etching, it should also be appreciated that these inventive aspects may also apply to other industrial processes using gases with environmental concerns. In particular, aspects of this disclosure may similarly apply to chemical vapor deposition processes, plasma cleaning operations, other etching chemistries beyond SF₆ (including NF₃, CF₄, CHF₃, and other halogenated compounds), and industrial processes outside semiconductor manufacturing that utilize specialty gases. The MOF capture system may be adapted for various process gases by selecting appropriate MOF materials with pore sizes tuned to the specific target molecules. For example, the same MOF structure that captures SF₆ may also effectively capture NF₃, CHF₃, and CF₄. The abatement and recycling approach described herein may be implemented in various vacuum-based processing systems with different chamber configurations, pumping arrangements, and process conditions. The multi-stage filtration concept can be adapted to protect the MOF from various process byproducts specific to different manufacturing processes, such as silicon tetrafluoride (SiF₄) from silicon etching, metal-containing compounds from metal etching, or carbon-based byproducts from photoresist stripping operations. Furthermore, the parallel container arrangement with valve systems for continuous operation may benefit any industrial process where system downtime for maintenance is costly, including flat panel display manufacturing, solar cell production, and various coating technologies.

The principles and systems described herein may be applied to any type of processing system where gas capture and recycling is desired, regardless of the specific pumping arrangement or chamber configuration. The abatement system may be integrated with various pumping schemes including roughing pump only configurations, roughing pump plus turbo pump arrangements, or other vacuum system designs. The process chamber may comprise any type of plasma processing system or non-plasma processing system, and may be configured for full wafer treatment or location-specific processing applications. The exhaust stream management approach is applicable across different semiconductor processing tools and manufacturing systems where recovery of particular gas species provides environmental or economic benefits.

Example embodiments of the invention are described below. Other embodiments can also be understood from the entirety of the specification as well as the claims filed herein.

Example 1. A processing system, the system including: a process chamber configured to process a substrate; an exhaust system coupled to the process chamber and configured to remove process effluent from the process chamber; and an abatement system including a first metal-organic framework (MOF) container coupled downstream of the exhaust system, where the first MOF container is configured to capture a first gas species of the process effluent.

Example 2. The system of example 1, where the exhaust system includes a turbo pump, a throttle valve, or a nitrogen gas source coupled to the turbo pump.

Example 3. The system of one of examples 1 or 2, further including a multi-stage filtration system coupled upstream of the first MOF container, the multi-stage filtration system being configured to remove reaction byproducts from the process effluent.

Example 4. The system of one of examples 1 to 3, where the multi-stage filtration system includes a filter, a neutralizer, or a fluorine species remover.

Example 5. The system of one of examples 1 to 4, further including a rough pump coupled between the exhaust system and the abatement system.

Example 6. The system of one of examples 1 to 5, further including a chemical supply system coupled to the process chamber and configured to supply a process gas into the process chamber for processing the substrate.

Example 7. The system of one of examples 1 to 6, where the first MOF container includes: a cylindrical chamber including a chamber wall; a support structure disposed within the cylindrical chamber; and a MOF granular material disposed within the cylindrical chamber and supported by the support structure, where the MOF granular material is configured to selectively capture the first gas species based on molecular size.

Example 8. The system of one of examples 1 to 7, further including a rough pump coupled downstream of the abatement system.

Example 9. The system of one of examples 1 to 8, further including: a second MOF container positioned parallel to the first MOF container; and a valve arrangement in the abatement system configured to direct the process effluent through a first MOF container while closing process effluent flow through the second MOF container.

Example 10. The system of one of examples 1 to 9, further including: a pressure monitoring system in the abatement system, the pressure monitoring system including a first pressure sensor positioned upstream of the first MOF container and a second pressure sensor positioned downstream of the first MOF container; and a controller coupled to the abatement system and programmed to: monitor a pressure differential between the first pressure sensor and the second pressure sensor, determine saturation of the first MOF container based on a change in the pressure differential, switch process effluent flow from the first MOF container to the second MOF container when the change in the pressure differential exceeds a predetermined threshold, and generate a notification indicating that the first MOF container is ready for extraction of the first gas species in the first MOF container.

Example 11. A processing system, the system including: an abatement system including a first metal-organic framework (MOF) container configured to capture a first gas species of a process effluent received from a process chamber; and a recycling system configured to couple to the first MOF container, the recycling system including: an extraction pump configured to create a pressure gradient to extract MOF captured gases including the first gas species from the first MOF container, and a purification system coupled downstream of the extraction pump and configured to increase concentration of the first gas species in the MOF captured gases.

Example 12. The system of example 11, where the recycling system further includes: a gas spectrometer coupled downstream of the purification system and configured to measure gas composition of the MOF captured gases and generate composition data indicating purity levels of the first gas species; and a distribution valve coupled to the gas spectrometer and configured to receive control signals from the gas spectrometer, where the distribution valve directs the MOF captured gases for storage when the composition data indicates the first gas species meets predetermined purity requirements.

Example 13. The system of one of examples 11 or 12, further including a controller coupled to the recycling system, the controller configured to: monitor gas composition data from the gas spectrometer; and control the distribution valve to direct the MOF captured gases to a storage container based on the gas composition data.

Example 14. The system of one of examples 11 to 13, further including a throttle valve coupled to the extraction pump and configured to control a flow rate of the MOF captured gases.

Example 15. The system of one of examples 11 to 14, further including a filter coupled between the extraction pump and the purification system and configured to remove particulates from the MOF captured gases.

Example 16. A method of operating a processing system, the method including: introducing process gases into a process chamber of the processing system; processing a substrate in the process chamber using the process gases; directing process effluent from the process chamber through a multi-stage filtration system, where the multi-stage filtration system removes reaction byproducts from the process effluent; and capturing a first gas species from the process effluent using a first metal-organic framework (MOF) container.

Example 17. The method of example 16, further including: closing process effluent flow to the first MOF container and redirecting process effluent flow to a second MOF container when the first MOF container is saturated with the first gas species; coupling the first MOF container to a recycling system; extracting MOF captured gases including the first gas species from the first MOF container; purifying the MOF captured gases to increase concentration of the first gas species in the MOF captured gases; and storing the MOF captured gases for reuse in the processing system.

Example 18. The method of one of examples 16 or 17, where the extracting includes applying a pressure differential to the first MOF container to induce desorption of the first gas species.

Example 19. The method of one of examples 16 to 18, further including analyzing composition of the MOF captured gases using a gas spectrometer after the purifying and before the storing.

Example 20. The method of one of examples 16 to 19, further including: adjusting a throttle valve or a rough pump coupled to the first MOF container to establish optimal pressure conditions for gas capture in the first MOF container.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1-8 may be combined in further embodiments. It is therefore intended that the appended claims encompass any such modifications or embodiments.

What is claimed is:

1. A processing system, the system comprising:
a process chamber configured to process a substrate;
an exhaust system coupled to the process chamber and configured to remove process effluent from the process chamber; and
an abatement system comprising a first metal-organic framework (MOF) container coupled downstream of the exhaust system, wherein the first MOF container is configured to capture a first gas species of the process effluent.

2. The system of claim 1, wherein the exhaust system comprises a turbo pump, a throttle valve, or a nitrogen gas source coupled to the turbo pump.

3. The system of claim 1, further comprising a multi-stage filtration system coupled upstream of the first MOF container, the multi-stage filtration system being configured to remove reaction byproducts from the process effluent.

4. The system of claim 3, wherein the multi-stage filtration system comprises a filter, a neutralizer, or a fluorine species remover.

5. The system of claim 3, further comprising a rough pump coupled between the exhaust system and the abatement system.

6. The system of claim 1, further comprising a chemical supply system coupled to the process chamber and configured to supply a process gas into the process chamber for processing the substrate.

7. The system of claim 1, wherein the first MOF container comprises:
a cylindrical chamber comprising a chamber wall;
a support structure disposed within the cylindrical chamber; and
a MOF granular material disposed within the cylindrical chamber and supported by the support structure, wherein the MOF granular material is configured to selectively capture the first gas species based on molecular size.

8. The system of claim 1, further comprising a rough pump coupled downstream of the abatement system.

9. The system of claim 1, further comprising:
a second MOF container positioned parallel to the first MOF container; and
a valve arrangement in the abatement system configured to direct the process effluent through the first MOF container while closing process effluent flow through a second MOF container.

10. The system of claim 8, further comprising:
a pressure monitoring system in the abatement system, the pressure monitoring system comprising a first pressure sensor positioned upstream of the first MOF container and a second pressure sensor positioned downstream of the first MOF container; and
a controller coupled to the abatement system and programmed to:
monitor a pressure differential between the first pressure sensor and the second pressure sensor,
determine saturation of the first MOF container based on a change in the pressure differential,
switch process effluent flow from the first MOF container to a second MOF container when the change in the pressure differential exceeds a predetermined threshold, and
generate a notification indicating that the first MOF container is ready for extraction of the first gas species in the first MOF container.

11. A processing system, the system comprising:
an abatement system comprising a first metal-organic framework (MOF) container configured to capture a first gas species of a process effluent received from a process chamber; and
a recycling system configured to couple to the first MOF container, the recycling system comprising:
an extraction pump configured to create a pressure gradient to extract MOF captured gases comprising the first gas species from the first MOF container, and
a purification system coupled downstream of the extraction pump and configured to increase concentration of the first gas species in the MOF captured gases.

12. The system of claim 11, wherein the recycling system further comprises:
a gas spectrometer coupled downstream of the purification system and configured to measure gas composition of the MOF captured gases and generate composition data indicating purity levels of the first gas species; and
a distribution valve coupled to the gas spectrometer and configured to receive control signals from the gas spectrometer, wherein the distribution valve directs the MOF captured gases for storage when the composition data indicates the first gas species meets predetermined purity requirements.

13. The system of claim 12, further comprising a controller coupled to the recycling system, the controller configured to:
monitor gas composition data from the gas spectrometer; and
control the distribution valve to direct the MOF captured gases to a storage container based on the gas composition data.

14. The system of claim 11, further comprising a throttle valve coupled to the extraction pump and configured to control a flow rate of the MOF captured gases.

15. The system of claim 11, further comprising a filter coupled between the extraction pump and the purification system and configured to remove particulates from the MOF captured gases.

16. A method of operating a processing system, the method comprising:
introducing process gases into a process chamber of the processing system;
processing a substrate in the process chamber using the process gases;
directing process effluent from the process chamber through a multi-stage filtration system, wherein the multi-stage filtration system removes reaction byproducts from the process effluent; and
capturing a first gas species from the process effluent using a first metal-organic framework (MOF) container.

17. The method of claim 16, further comprising:
closing process effluent flow to the first MOF container and redirecting process effluent flow to a second MOF container when the first MOF container is saturated with the first gas species;
coupling the first MOF container to a recycling system;
extracting MOF captured gases comprising the first gas species from the first MOF container;
purifying the MOF captured gases to increase concentration of the first gas species in the MOF captured gases; and
storing the MOF captured gases for reuse.

18. The method of claim 17, wherein the extracting comprises applying a pressure differential to the first MOF container to induce desorption of the first gas species.

19. The method of claim 17, further comprising analyzing composition of the MOF captured gases using a gas spectrometer after the purifying and before the storing.

20. The method of claim 16, further comprising:
adjusting a throttle valve or a rough pump coupled to the first MOF container to establish optimal pressure conditions for gas capture in the first MOF container
